(19) United States
(12) Patent Application Publication
(10) Pub. No.: US 2013/0106434 A1
(43) Pub. Date: May 2, 2013

(54) ELECTROSTATIC FIELD INTERFERENCE TESTING APPARATUS AND METHOD USING THE SAME

(71) Applicants: WEN-CHAO CHUNG, NEW TAIPEI CITY (TW); CHIN-LUNG CHENG, NEW TAIPEI CITY (TW); CHIA-HENG WEI, NEW TAIPEI CITY (TW); YUEH-PENG HSIUNG, NEW TAIPEI CITY (TW)

(72) Inventors: WEN-CHAO CHUNG, NEW TAIPEI CITY (TW); CHIN-LUNG CHENG, NEW TAIPEI CITY (TW); CHIA-HENG WEI, NEW TAIPEI CITY (TW); YUEH-PENG HSIUNG, NEW TAIPEI CITY (TW)

(73) Assignee: WISTRON CORP., NEW TAIPEI CITY (TW)

(21) Appl. No.: 13/492,735

(22) Filed: Jun. 8, 2012

(30) Foreign Application Priority Data
Oct. 28, 2011 (TW) 100139343

(51) Int. Cl. G01R 27/26

(52) U.S. Cl. 324/612

(57) ABSTRACT

An electrostatic field interference testing apparatus and a method using the same are disclosed. The electrostatic field interference testing apparatus includes an electrostatic discharge generator and a conducting element placed in the neighborhood of an output end of the electrostatic discharge generator where an electrostatic discharge takes place and electrically coupled to a ground end. When the electrostatic discharge generator performs an air discharge on the conducting element, a testing electromagnetic field may be generated as the result of a transient current spike. The testing electromagnetic field is thereafter utilized to determine whether the protection of a DUT against electric/magnetic field strength is suitable.

### BACKGROUND OF THE DISCLOSURE

1. Field of the Disclosure

The present disclosure relates to an electrostatic discharge testing apparatus, and more particularly, to an electrostatic field interference testing apparatus and a method using the same.

2. Description of Related Art

Tests of electromagnetic compatibility (EMC) for growingly sophisticated electronic devices are critical in ensuring the stability of the electronic devices. Once the electronic device passes its corresponding EMC test, when in operation such electronic device would not be magnetically interfering with another electronic device in operation as well. The EMC test generally includes an electromagnetic interference (EMI) test and an electromagnetic susceptibility (EMS) test.

In the EMC test, an electrostatic discharge generator is always employed. The conventional electrostatic discharge generator is capable of generating an electrostatic discharge so that any failure of the electronic device to comply with an EMC standard may be identified and corrected. FIG. 1 shows a schematic diagram of an external control system and a touch device according to one embodiment of the present disclosure. Typically, a ground plane of a screw hole 111 or 112 is subject to the EMC test first as the screw hole 111 or 112 is usually associated with the electrostatic discharge. For the EMC test for the screw hole 111 or 112 to be accomplished, the electrostatic discharge generator is aimed at the screw hole 111 or 112 before outputting/generating the electrostatic discharge.

However, it has been widely perceived that the conventional EMC test could just roughly identify certain areas (such as an area 120) of a DUT (DUT) may be susceptible to the electrostatic discharge. Moreover, the number of electronic components in the identified area 120 may further confound the result of the EMC test especially when the number of the electronic components in the identified area is significant. As such, additional resource may need to be devoted to identifying which part of DUT is susceptible to the electrostatic discharge more accurately and more time would be consumed accordingly.

### SUMMARY OF THE DISCLOSURE

The primary objective of the present disclosure is to provide an electrostatic field interference testing apparatus having an electrostatic discharge generator that is capable of performing an air discharge on a conducting element to generate a testing magnetic field. The generated testing magnetic field may be utilized to test the EMC capability and the protection capability against the electrostatic discharge, before any areas of the DUT that may be susceptible to the electrostatic discharge could be identified with more accuracy.

The electrostatic discharge generator includes an output end from which the electrostatic discharge is outputted, while the conducting element is made of conducting material and electrically coupled to a ground end. The conducting element is placed in the neighborhood of the output end of the electrostatic discharge generator so that when the electrostatic discharge generator performs the electrostatic discharge on the conducting element a corresponding testing magnetic field could be generated.

The electrostatic field interference testing apparatus may further include an isolating element placed between the DUT and the conducting element for protecting the DUT from being damaged by the electrostatic discharge.

The electrostatic field interference testing apparatus may further include a testing platform and a mechanical arm for positioning the electrostatic discharge generator and the conducting element for finalizing the EMC test for the DUT.

The generated testing magnetic field may be used to simulate electric/magnetic field strength and further determine an impact of the electric/magnetic field strength on the DUT. As such, the EMC test could be finalized more promptly and the areas susceptible to the electrostatic discharge may be identified with more accuracy.

In order to further the understanding regarding the present disclosure, the following embodiments are provided along with illustrations to facilitate the disclosure of the present disclosure.

### BRIEF DESCRIPTION OF THE DRAWINGS

FIG. 1 shows a schematic diagram of an external control system and a touch device according to one embodiment of the present disclosure;

FIG. 2A is a schematic diagram showing an electrostatic field interference testing apparatus according to one embodiment of the present disclosure;

FIG. 2B shows a schematic diagram illustrative of a spatial relationship between the electrostatic discharge generator, the conducting element, the isolating element, and the DUT in FIG. 2A according to one embodiment of the present disclosure;

FIG. 3A shows a schematic diagram of another electrostatic field interference testing apparatus according to one embodiment of the present disclosure;

FIG. 3B illustrates a schematic diagram of another electrostatic field interference testing apparatus according to one embodiment of the present disclosure;

FIG. 4 is a schematic diagram showing another electrostatic field interference testing apparatus according to one embodiment of the present disclosure; and

FIG. 5 illustrates a flow chart of a method for testing electrostatic field interference according to one embodiment of the present disclosure.

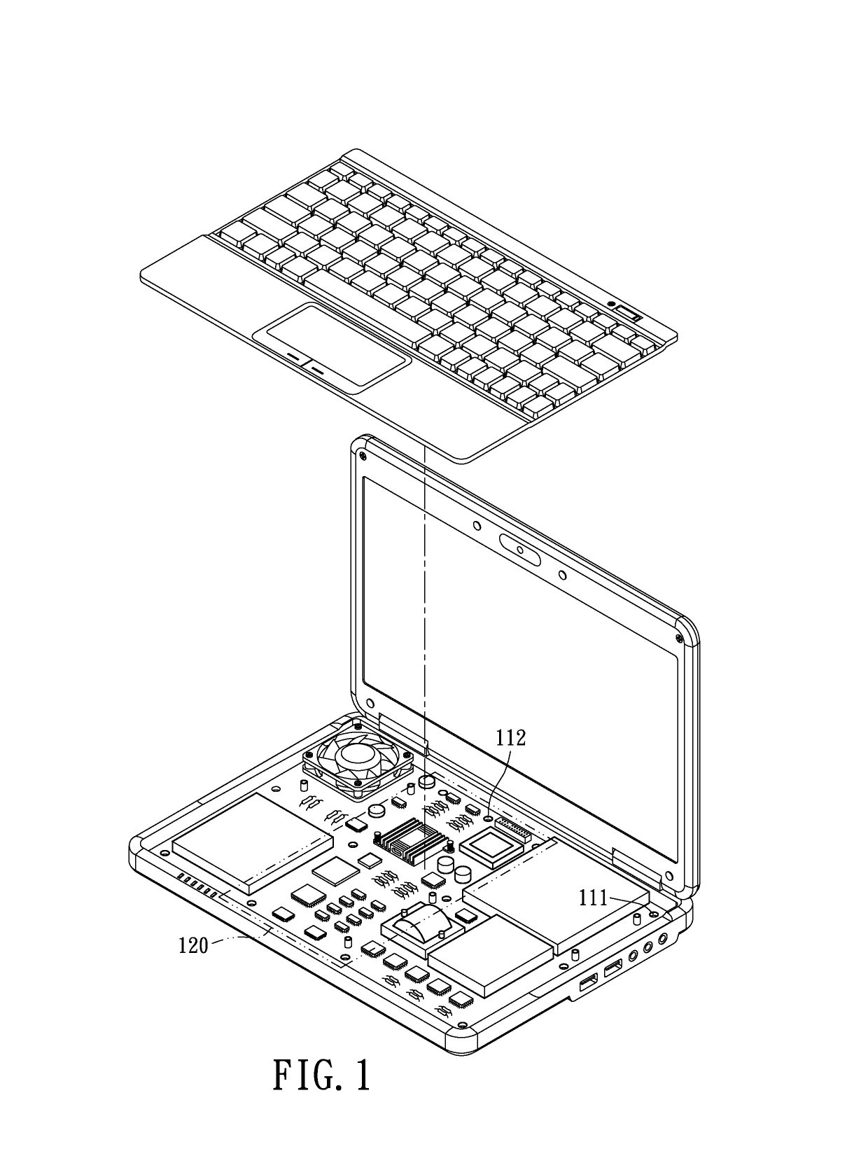

### DETAILED DESCRIPTION OF THE PREFERRED EMBODIMENTS

The aforementioned illustrations and following detailed descriptions are exemplary for the purpose of further explaining the scope of the present disclosure. Other objectives and advantages related to the present disclosure will be illustrated in the subsequent descriptions and appended drawings.

### First Embodiment of the Present Disclosure

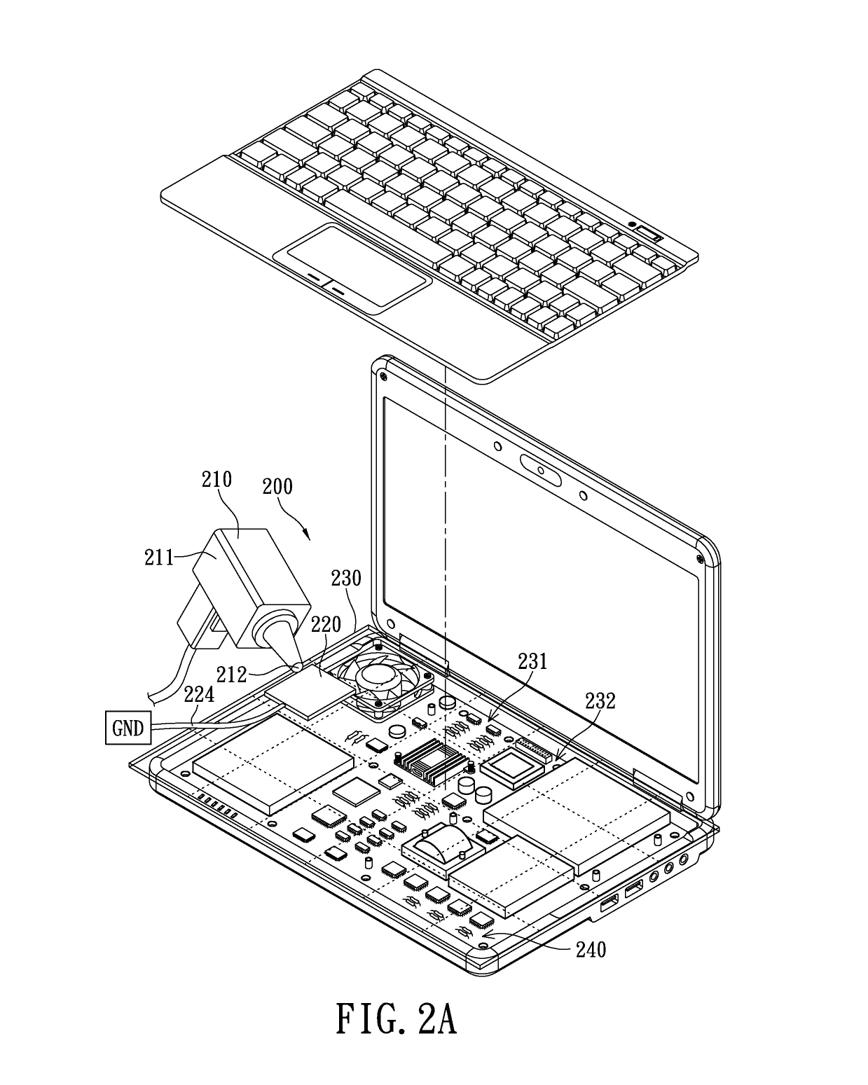

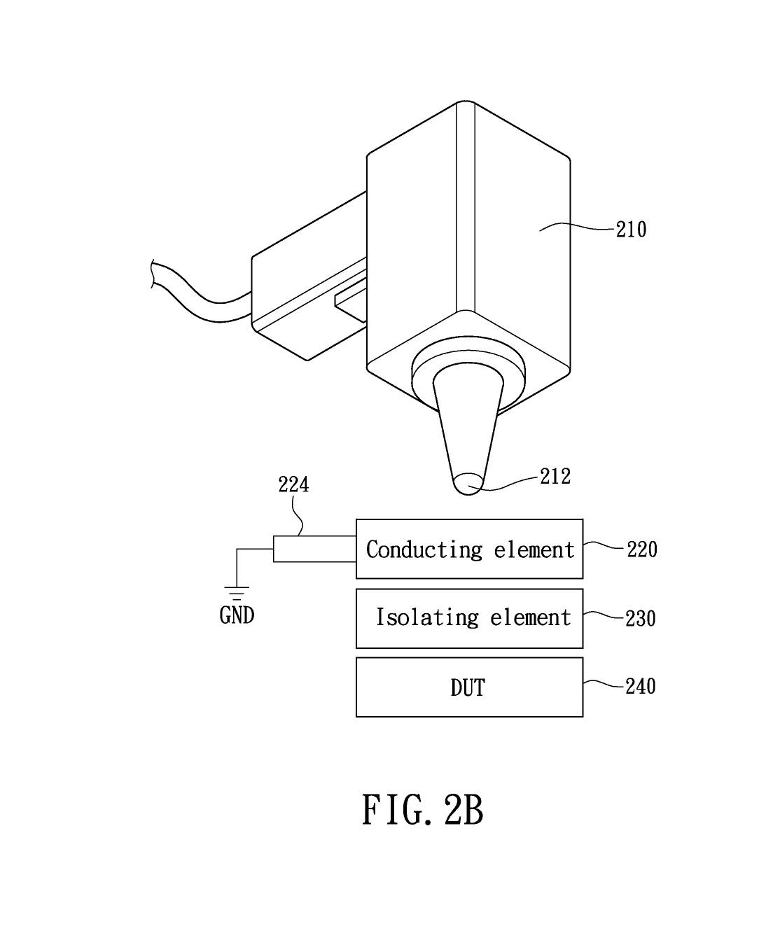

FIG. 2A is a schematic diagram showing an electrostatic field interference testing apparatus 200 according to one embodiment of the present disclosure. The electrostatic field interference testing apparatus 200 may include an electrostatic discharge generator 210, a conducting element 220, and an isolating element 230. The electrostatic discharge generator 210 may further input an output end 212 for outputting high-voltage pulses for generation of an electrostatic discharge. In one implementation, the electrostatic discharge generator 210 is an electrostatic discharge gun (ESD-gun) with a muzzle as the output end 212 thereof and a body 211 to be held by human operators. The conducting element 220 may be made of conducting material and electrically connected to a ground end through a conducting wire 224. In one implementation, the conducting element is a metal plate, while in another implementation the conducting element 220 is in the form of thin metal such as an aluminum foil.

The conducting element 220 may be placed in the neighborhood of the output end 212, so as to facilitate the generation of a testing electromagnetic field when the electrostatic discharge generator 210 operates to perform an air discharge on the conducting element 220. Specifically speaking, the testing electromagnetic field, which may simulate an electrostatic field when an electrostatic discharge occurs, is generated because of a current associated with the electrostatic discharge flows on the conducting element 220. The electromagnetic field may also test the protection capability of a device under test (DUT) 240 against the electrostatic field. For achieving that particular goal, the testing electromagnetic field is generated by the operation of the electrostatic discharge generator 210 to perform the air discharge above the DUT 240, so that an area of the DUT 240 that is susceptible to malfunction may be identified.

In one implementation, the isolating element 230 is a plastic pad that is placed at one side of the output end 212 with the conducting element 220 placed on the other side of the output end 212. In other words, the isolating element 230 may be placed between the conducting element 220 and the DUT 240. And the isolating element 230 may be larger than the conducting element 220 in size.

The isolating element 230 may prevent the current associated with the electrostatic discharge generated by the electrostatic discharge generator 210 from flowing into the DUT 240 and thus damaging the DUT 240. In one implementation, the DUT 240 is a motherboard of a computer or a motherboard of a server.

In conjunction with FIG. 2A, please refer to FIG. 2B showing a schematic diagram illustrative of a spatial relationship between the electrostatic discharge generator 210, the conducting element 220, the isolating element 230, and the DUT 240 according to one embodiment of the present disclosure.

Despite the conducting element 220 is between the electrostatic discharge generator 210 and the isolating element 230, the conducting element 220 is in no physical contact with the electrostatic discharge generator 210 and the isolating element 230 according to FIG. 2B. Plus, the isolating element 230 may be between the conducting element 220 and the DUT 240 when the conducting element 220 may be spaced from the DUT 240 by a predetermined distance. In one implementation, the predetermined distance is 1.5 centimeters.

Though the electrostatic discharge generator 210, the conducting element 220, and the isolating element 230 may be separated from each other when implemented, they may be placed on the same structure. For example, the isolating element 230 and the conducting element 220 may be connected to the body of the electrostatic discharge generator 210 by an adjusting mechanical device (e.g., an adjusting mechanical arm) allowing for the positioning of the conducting element 220 to be facilitated.

Please refer back to FIG. 2A. The conducting element 220 may be implemented in terms of a connecting wire. For example, a universal serial bus (USB)-based connecting wire or a high definition multimedia interface (HDMI)-based connecting wire may be utilized to serve as the conducting element 220. When the USB-based connecting wire is used, one end of the USB-based connecting wire may serve as the conducting element, while the other end of the USB-based connecting wire may be connected to a ground end (GND). It is worth noting that the ground end may be a common ground for the conducting element 220 and the electrostatic discharge generator 210.

The isolating element 230 may be placed above the DUT 240 in order to prevent the DUT 240 from being damaged by the electrostatic discharge. The conducting element 220 may be placed ahead of the muzzle (or the output end) 212 of the electrostatic discharge generator 210, before the electrostatic discharge generator 210 could perform the air discharge at least at the 8-KV level on the conducting element 220. When the electrostatic discharge is delivered to the conducting element 220 as the result of the air discharge, a transient current spike may be generated and guided to the ground end (GND) allowing for the testing electromagnetic field to be generated.

Since the transient current spike may cause an electric/magnetic field strength that would likely interfere with signal lines or chipsets of the DUT 240, the testing electromagnetic field generated above the DUT 240 as the result of the transient current spike may be utilized for the determination of whether the DUT 240 malfunctions or is damaged. The determination may be on basis of an output of the DUT 240 present the testing electromagnetic field. When the DUT 240 malfunctions as the result, an area of the DUT 240 under the conducting element 220 may fall into the category of being weak in electrostatic protection or electromagnetic compatibility.

For the information regarding the electromagnetic compatibility of the DUT 240, the isolating element 230 may have multiple testing areas 231 and 232 defined thereon. The location and the size of the testing areas 231 and 232 may be predetermined. In one implementation, the testing area 231 may be rectangular in shape while the testing area 232 may be circular in shape.

The conducting element 220 may be moved to positions above the testing areas 231 and 232 before the corresponding testing electromagnetic fields could be generated for testing whether areas of the DUT 240 that correspond to the testing areas 231 and 232 are in compliance with standards of electromagnetic compatibility. The sequence for moving around the conducting element 220 may be predetermined as well, when the outputs of the electrostatic discharge generator 210 may vary from time to time in order to satisfy the needs of the electric/magnetic field strength. For example, the outputs of the electrostatic discharge generator 210 may be 8 KV or 9 KV, so as to generate the required field strength, though the field strength of the electrostatic discharge generator is not limited as the result. And over the course of the testing for the testing areas 231 and 232 the output of the DUT 240 may be utilized to determine which testing area (e.g., the testing area 231) may malfunction.

Therefore, the human operators may be able to perform the electromagnetic compatibility test and shorten the time consumed for the test to be finalized. And the human operators may respond to the results of the tests more promptly. Moreover, with the isolating element 230 the electrostatic discharge may not flow into the DUT 240, minimizing the occurrence of the components to be tested 240 is damaged by the electrostatic discharge. When necessary, it is worth noting that the isolating element 230 may be removed when the test is conducted. In other words, the electrostatic field interference testing apparatus 200 may be consisted of the electrostatic discharge generator 210 and the conducting element 220.

Additionally, the operation of the electrostatic discharge generator and the positioning thereof could be controlled automatically (e.g., by a mechanical arm). The positioning of the conducting element 220 may be subject to the automatic control also.

### Second Embodiment of the Present Disclosure

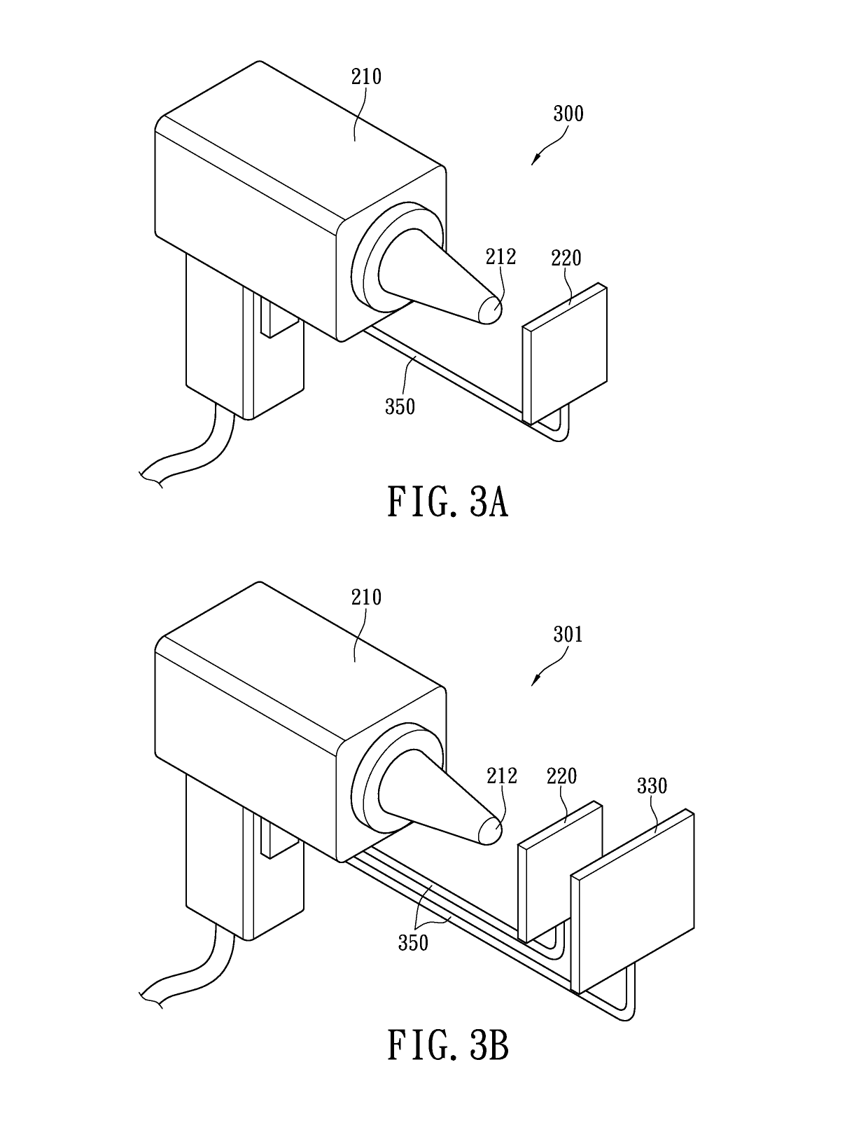

The conducting element 220 may be integrated with the electrostatic discharge generator 210 as shown in FIG. 3A in which a schematic diagram of another electrostatic field interference testing apparatus 300 according to one embodiment of the present disclosure is illustrated. The conducting element 220 may be connected to or integrated with the electrostatic discharge generator 210 by an adjusting arm 350. The conducting element 220 and the electrostatic discharge generator 210 may share the same ground in one implementation, while in another implementation the conducting element 220 and the electrostatic discharge generator 210 may be connected to their respective grounds.

The adjusting arm 350 may be a retractable pole or a flexible pole for adjusting the position of the conducting element 220 and maintaining the conducting element 220 at a predetermined position so as to ensure the conducting element 220 is at the neighborhood of the output end 212 of the electrostatic discharge generator 210. When test for the DUT 240 is conducted, the isolating element 230 may be placed above the DUT 240 before the electrostatic field interference testing apparatus 300 may be turned on.

### Third Embodiment of the Present Disclosure

Please refer to FIG. 3B illustrating a schematic diagram of another electrostatic field interference testing apparatus 301 according to one embodiment of the present disclosure. One difference between the electrostatic field interference testing apparatus 300 in FIG. 3A and the electrostatic field interference testing apparatus 301 in FIG. 3B lies in the placement of an isolating element 330. The isolating element 330 is integrated with the electrostatic discharge generator 210 with the size thereof varying in accordance with the size of the electrostatic discharge generator 210. For example, the isolating element 330 may be larger than the conducting element 220 in size.

With the electrostatic field interference testing apparatus 301, which may be capable of directly conducting the test since having the conducting element 220 and the isolating element 330 integrated, the electrostatic field interference testing apparatus 301 may be positioned above the DUT 240, without further having the isolating element 330 placed.

### Fourth Embodiment of the Present Disclosure

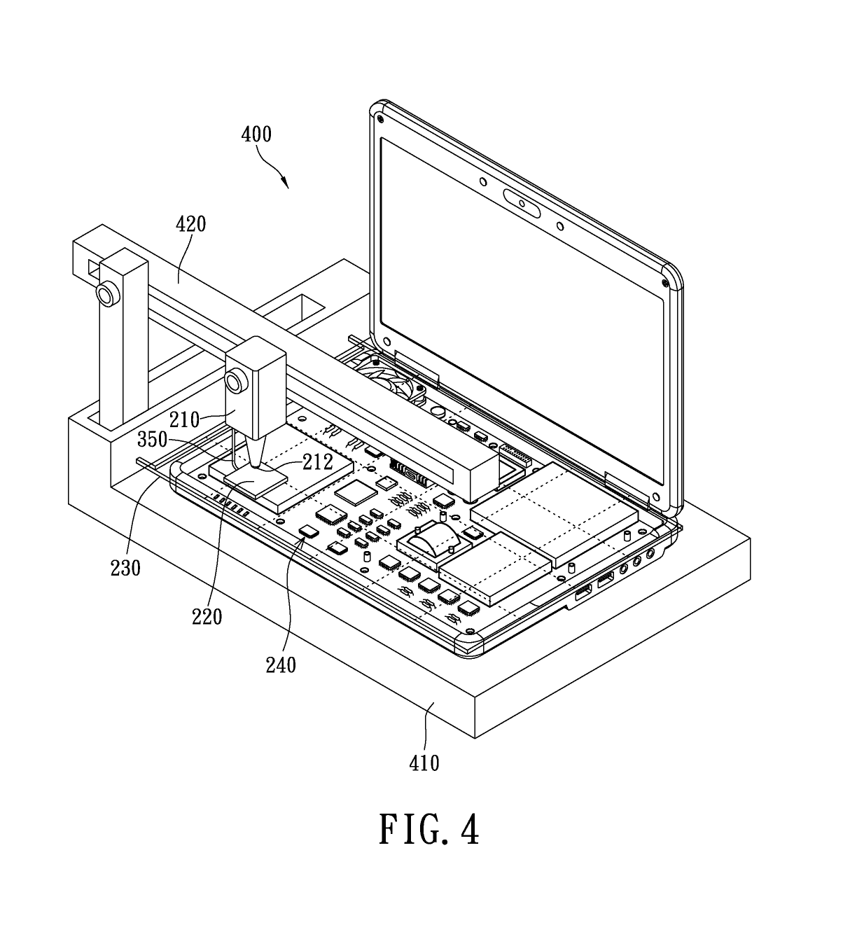

FIG. 4 is a schematic diagram showing another electrostatic field interference testing apparatus 400 according to one embodiment of the present disclosure. The electrostatic field interference testing apparatus 400 may include a testing platform 410, a mechanical arm 420, the electrostatic discharge generator 210, the conducting element 220, and the isolating element 230. The testing platform 410 may have the DUT 240 placed thereon, while the mechanical arm may be equipped with the electrostatic discharge generator 210, the conducting element 220, and the isolating element 230. Thus, the electrostatic discharge generator 210, the conducting element 220, and the isolating element 230 may be moved around and positioned by the mechanical arm 420. It is worth noting that the conducting element 220 may be placed in the neighborhood of the output end 212 of the electrostatic discharge generator 210, with the isolating element 230 placed between the testing platform 410 and the conducting element 220. The space between the isolating element 230 and the testing platform 410 may be where the DUT 240 is placed.

The isolating element 230 may be connected to the mechanical arm 420 or disposed on the testing platform 410 in a removable fashion in order to prevent the electrostatic discharge from damaging the DUT 240. The isolating element 230 may be integrated with the electrostatic discharge generator 210 as shown in FIG. 3B. The conducting element 220, meanwhile, may be integrated with the electrostatic discharge generator 210 through the adjusting arm 350 as shown in FIG. 3A. Plus, the conducting element 220 may be fixed to the mechanical arm 420 so as to be moved synchronously with the electrostatic discharge generator 210.

The electrostatic field interference testing apparatus 400 may be programmed to perform the test automatically, while positioning the mechanical arm, and powering the electrostatic discharge generator 210 for the test to begin.

The electrostatic field interference testing apparatus 400 may have a power supply and an output device (not shown) allowing for the DUT 240 to be powered and the display of the output of the DUT 240, respectively. The electrostatic field interference testing apparatus 400 may also have a processing unit and a memory unit.

The electrostatic field interference testing apparatuses 200, 300, 301, and 400 may be considered as an electrostatic field simulator that is capable of simulating the generation of the electrostatic field arising out of the electrostatic discharge on basis of which the area of the DUT 240 may be identified before any further analysis could be performed and any further action could be taken.

### Fifth Embodiment of the Present Disclosure

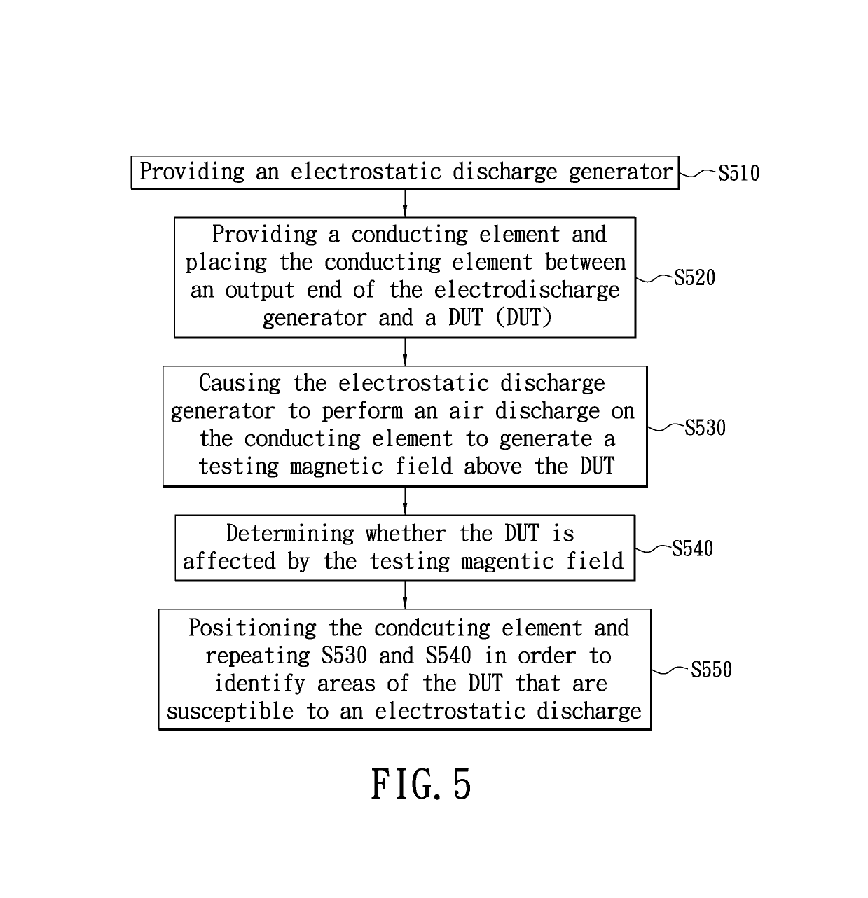

FIG. 5 illustrates a flow chart of a method for testing electrostatic field interference according to one embodiment of the present disclosure.

In step S501, the method for testing the electrostatic field interference provides the electrostatic discharge generator 210. The method further includes providing the conducting element 220 and placing the conducting element 220 between the output end 212 of the electrostatic discharge generator 210 and the DUT 240, with the conducting element 220 placed in the neighborhood of the output end 212 of the electrostatic discharge generator 210 (step S520). The method further includes causing the electrostatic discharge generator 210 to perform the air discharge on the conducting element 220 so as to generate the testing electromagnetic field above the DUT 240 (step S530), and determining whether the DUT 240 malfunctions as the result of the testing electromagnetic field (step S540).

The method also includes repositioning the conducting element 220 and repeating S530 and S540 for further identifying the areas of the DUT 240 that may malfunction (step S550). And when the area of the DUT 240 has been identified as “malfunctioning” additional verification and debugging for that particular area of the DUT 240 may be performed.

In summary, the method according to the present disclosure employs the electrostatic discharge generator 210 and the conducting element 220 to be placed at a predetermined position with respect to the DUT 240 before causing the electrostatic discharge generator 210 to perform the air discharge on the conducting element 220 for the generation of the testing electromagnetic field in order to identify the area of the DUT is affected by the testing electromagnetic field, and whether the electrostatic discharge protection and the electromagnetic compatibility associated with the identified area meet the needs.

The descriptions illustrated supra set forth simply the preferred embodiments of the present disclosure; however, the characteristics of the present disclosure are by no means restricted thereto. All changes, alternations, or modifications conveniently considered by those skilled in the art are deemed to be encompassed within the scope of the present disclosure delineated by the following claims.

What is claimed is:

1. An electrostatic field interference testing apparatus, comprising:
an electrostatic discharge generator having an output end; and
a conducting element made of a conducting material and electrically coupled to a ground end;
wherein the conducting element is placed in a neighborhood of the output end of the electrostatic discharge generator so as to facilitate a generation of a testing electromagnetic field when the electrostatic discharge generator performs an air discharge on the conducting element.

2. The electrostatic field interference testing apparatus according to claim 1, wherein the electrostatic discharge generator is an electrostatic discharge gun (ESD-gun) having a body and the output end.

3. The electrostatic field interference testing apparatus according to claim 1, further comprising a conducting wire connected to the conducting element and the ground end.

4. The electrostatic field interference testing apparatus according to claim 1, further comprising an adjusting arm coupled to the conducting element and the electrostatic discharge generator, for positioning the conducting element and maintaining the conducting element at a position.

5. The electrostatic field interference testing apparatus according to claim 1, further comprising an isolating element placed at a first side opposite to a second side where the output end locates with respect to the conducting element wherein the isolating element is larger than the conducting element in size.

6. The electrostatic field interference testing apparatus according to claim 5, wherein the isolating element has a plurality of testing areas defined thereon.

7. The electrostatic field interference testing apparatus according to claim 1, wherein the conducting element includes a metal plate.

8. The electrostatic field interference testing apparatus according to claim 1, further comprising a testing platform on which a DUT is placed, a mechanical arm placed on the testing platform for connecting the electrostatic discharge generator with the conducting element, and an isolating element placed on the testing platform and located between the conducting element and the testing platform.

9. A method for testing an electrostatic field interference capable of performing an electrostatic field interference test on a DUT, comprising:
providing an electrostatic discharge generator;
providing a conducting element and placing the conducting element between an output end of the electrostatic discharge generator and the DUT;
causing the electrostatic discharge generator to perform an air discharge on the conducting element for facilitating a generation of a testing electromagnetic field above the DUT;
determining whether the DUT is affected by the testing electromagnetic field; and
positioning the conducting element when repeating facilitating the generation of the testing electromagnetic field and determining whether the DUT is affected by the testing electromagnetic field, in order to identify an area corresponding to which the DUT is positioned is susceptible to malfunction.

10. The method according to claim 9, wherein providing the conducting element further comprises providing a conducting wire for electrically connecting the conducting element to a ground end.

11. The method according to claim 9, wherein providing the conducting element further comprises providing an adjusting arm connected to the conducting element and the electrostatic discharge generator for positioning the conducting element and maintaining the conducting element at a position.

12. The method according to claim 9, wherein providing the conducting element further comprises providing an isolating element and placing the isolating element between the conducting element and the DUT.

13. The method according to claim 12, wherein the isolating element has a plurality of testing areas defined thereon.

14. The method according to claim 9, wherein the conducing element is a metal plate.

15. The method according to claim 9, wherein the electrostatic discharge generator is an electrostatic discharge gun (ESD-gun) having a body and the output end.
